(19) United States
(12) Patent Application Publication
(10) Pub. No.: US 2007/0205512 A1
(43) Pub. Date: Sep. 6, 2007

(54) Solder bump structure for flip chip package and method for manufacturing the same

(76) Inventors: In-Young Lee, Yongin-si (KR); Gu-Sung Kim, Seongnam-si (KR); Se-Young Jeong, Seoul (KR); Sun-Young Park, Iksan-si (KR)

Correspondence Address: HARNESS, DICKEY & PIERCE, P.L.C., P.O. BOX 8910, RESTON, VA, 20195, US

(21) Appl. No.: 11/785,980

(22) Filed: Apr. 23, 2007

Related U.S. Application Data
(62) Division of application No. 10/897,124, filed on Jul. 23, 2004.

(30) Foreign Application Priority Data
Dec. 12, 2003 (KR) 2003-90682

(51) Int. Cl. H01L 23/48

(52) U.S. Cl. 257/738; 257/E23.021

(57) ABSTRACT

A solder bump structure may have a metal stud formed on a chip pad of a semiconductor chip. Surfaces of the metal stud may be plated with a solder. The metal stud may be located on a substrate pad of the substrate. The substrate pad may have a pre-solder applied thereto. After a solder reflow, the solder bump may have a concave shape.

### RELATED APPLICATION

This U.S. non-provisional application claims priority under 35 U.S.C. §119 from Korean Patent Application No. 2003-90682 filed on Dec. 12, 2003, the entire contents of which are hereby incorporated by reference.

### BACKGROUND OF THE INVENTION

1. Field of the Invention

The present invention relates generally to semiconductor packaging technology, and more particularly, to a solder bump structure for a flip chip package.

2. Description of the Related Art

As the operating speed of integrated circuit chips becomes higher and the number of input/output pins increases, conventional wire bonding technology may be limited. Therefore, attention has been focused on a flip chip technology as a replacement for the wire bonding technology. The flip chip technology may be characterized by solder bumps formed on input/output pads of a semiconductor chip. A conventional solder bump structure is illustrated in FIG. 1. Referring to FIG. 1, a chip pad 12 and a passivation layer 14 may be formed on an active surface of a semiconductor chip 10. A solder bump 30 may be formed on the chip pad 12. At least one under barrier metallurgy (UBM) 16 may be formed between the chip pad 12 and the solder bump 30. A substrate 20 may have a substrate pad 22 and a protection layer 24. The substrate pad 22 may have a pre-solder applied thereto.

The solder bump 30 may electrically and mechanically connect the semiconductor chip 10 to the substrate 20. The solder bump 30 may serve as a channel of electrical signals and a mechanical joint between the semiconductor chip 10 and the substrate 20. The size of the solder bump 30 for a flip chip package may be relatively small. To increase the bonding strength of the solder bump 30, an underfill material 40 may also be interposed between the semiconductor chip 10 and the substrate 20.

The underfill material 40 may flow into a space between the semiconductor chip 10 and the substrate 20 via capillary action. For an effective underfill process, the solder bump 30 may have a height to facilitate the underfill process. However, formation of the solder bump 30 having a desired height may inevitably involve an excessive solder plating in the manufacture of the solder bump 30.

FIG. 2 shows a process that may be implemented for manufacturing the conventional solder bump 30 depicted in FIG. 1. Referring to FIG. 2, openings of a photoresist 50 may be plated with solders 32. After the plating process, the photoresist 50 may be removed. Then, a portion of the UBM 16 may be removed. The solders 32 may then be reflowed. A sufficient amount of solder 32 may be plated to obtain solder bumps of a desired size, which may cause the solders 32 to brim over the photoresist 50 as shown in FIG. 2, for example in the shape of a mushroom. The solder plating may be performed so that a distance (b) exists between the solders 32 to avoid a contact of adjacent solders 32.

The solders 32 of a mushroom shape may cause an increase of the solder size (a) and formation of the distance (b) between adjacent solders 32, which may limit the pitch (d) of the resulting solder bumps 30. Thus, according to conventional wisdom, it may be difficult to form solder bumps having a finer pitch.

If the size of the UBM (e.g., the width of the UBM 16 of FIG. 1 or (c) of FIG. 2) is reduced, the bump pitch (d) may be reduced to some extent. However, the excessive size (a) of the mushroom shaped solder 32 and the distance (b) between the solders may prevent the realization of a finer pitch structure. Moreover, if the height of the solder bump 30 is reduced, the bump pitch (d) may be reduced. However, the reduction of the solder bump height may be limited since a sufficient height may be necessary to facilitate the underfill process.

FIGS. 3A and 3B are cross-sectional views of another example of the conventional solder bump structure. Referring to FIG. 3A, the height of the photoresist 50 may be increased so that the solders 32 are not formed of a mushroom shape. In this way, the bump pitch (e) may be reduced. However, after a solder reflow process, the bumps 30 may have a spherical shape as shown in FIG. 3B. This may reduce the distance (f) between adjacent bumps 30. Therefore, it may be difficult to achieve a finer pitch structure with the spherical solder bumps 30.

### SUMMARY OF THE INVENTION

An exemplary embodiment of the present invention may be directed to a solder bump structure having a concave shape. The concave shape may be provided in a middle of the solder bump.

Another exemplary embodiment of the present invention may be directed to a method for manufacturing a solder bump having a concave shape.

According to an exemplary embodiment of the present invention, the solder bump structure may have a semiconductor chip, a substrate, and a solder bumps. The semiconductor chip has an active surface on which a chip pad may be formed. The substrate has a substrate pad that may correspond to the chip pad. The solder bump may be formed between the chip pad and the substrate pad. The solder bump may have a concave shape in the middle thereof. The concave shape may be symmetrical and extend the entire length of the solder bump existing between the semiconductor chip and the substrate. Alternatively, only a portion of the length of the solder bump may have a concave shape and/or the concave shape may be asymmetrical.

According to an exemplary embodiment, the solder bump structure may include a metal stud and an under barrier metallurgy (UBM). The metal stud may be embedded within the solder bump. The UBM may be located between the solder bump and the chip pad.

According to another exemplary embodiment of the present invention, a method for manufacturing a solder bump may involve forming the metal stud on the chip pad of the semiconductor chip. A solder may be formed on a surface of the metal stud. The metal stud may be located on the substrate pad of the substrate. After a solder reflow process, the solder bump may have a concave shape.

According to an exemplary embodiment, the method for manufacturing a solder bump may involve applying a photoresist on the semiconductor chip. An opening may be formed in the photoresist and then filled with a metal material. The photoresist may be a positive photoresist. Forming the solder may involve forming a second opening in the photoresist to expose the metal stud and plating an exposed surface of the metal stud with the solder. A pre-solder may be applied on the substrate pad before the metal stud is located on the substrate pad of the substrate. The UBM may be formed on the chip pad of the semiconductor chip before the metal stud is formed on the chip pad of the semiconductor chip.

According to another exemplary embodiment, the solder bump structure may include a semiconductor chip, a substrate, and a solder bump electrically connecting the semiconductor chip to the substrate. The solder bump may be shaped so that a profile of the solder bump is widest at a solder bump surface in contact with at least one of the semiconductor chip and the substrate.

### BRIEF DESCRIPTION OF THE DRAWINGS

Exemplary, non-limiting embodiments of the present invention will be described with reference to the accompanying drawings, wherein like reference numerals designate like structural elements.

FIG. 1 is a cross-sectional view of a conventional solder bump structure for a flip chip package.

FIG. 2 is a cross-sectional view of a process that may be implemented for manufacturing the conventional solder bump of FIG. 1.

FIG. 3A is a cross-sectional view of a process that may be implemented for manufacturing another example of a conventional solder bump structure.

FIG. 3B is a cross-sectional view of the conventional solder bump structure that may be manufactured by the process shown in FIG. 3A.

FIG. 4 is a cross-sectional view of a solder bump structure in accordance with an exemplary, non-limiting embodiment of the present invention.

FIGS. 5A through 5K are cross-sectional views of an exemplary method that may be implemented for manufacturing the solder bump structure depicted in FIG. 4.

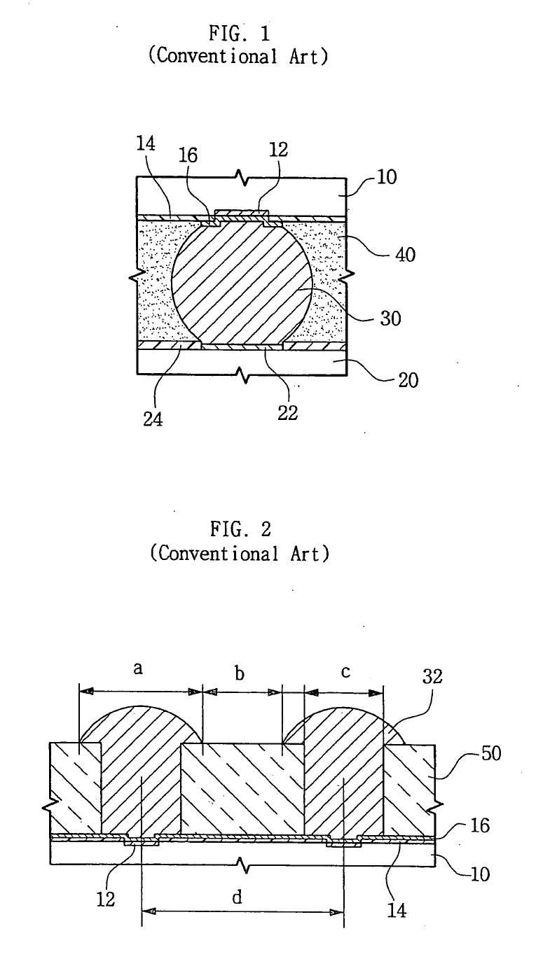

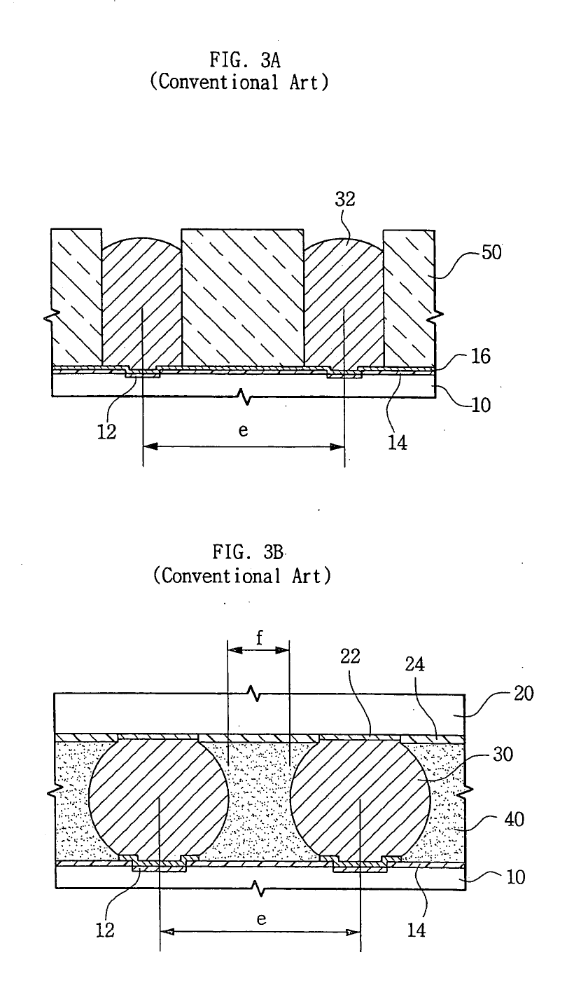

### DETAILED DESCRIPTION OF EXEMPLARY, NON-LIMITING EMBODIMENTS OF THE INVENTION

Exemplary, non-limiting embodiments of the present invention will be described below with reference to the accompanying drawings. It will be appreciated that the figures are not drawn to scale. Rather, for simplicity and clarity of illustration, the dimensions of some of the illustrated elements are exaggerated relative to other elements. Although the accompanying drawings show one or two solder bumps, it will be appreciated that a plurality of solder bumps may be arranged over an active surface of a semiconductor chip.

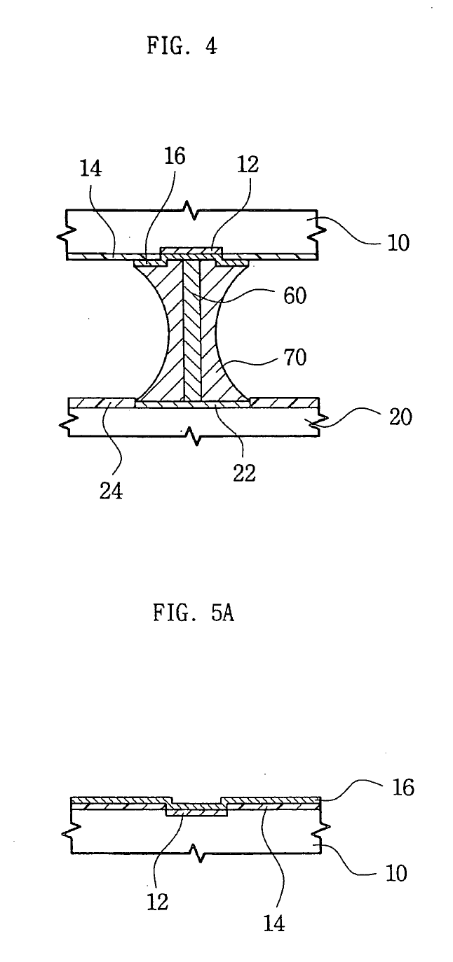

FIG. 4 is a cross-sectional view of a solder bump structure for a flip chip package in accordance with an exemplary embodiment of the present invention. Referring to FIG. 4, a semiconductor chip 10 may have an active surface on which a plurality of chip pads 12 are arranged. A passivation layer 14 may cover the active surface of the semiconductor chip 10 except for the chip pad 12. An under barrier metallurgy (UBM) 16 may be formed on the chip pad 12 and at least a portion of the passivation layer 14. A substrate 20 may be located opposite to the active surface of the semiconductor chip 10. The substrate 20 may have a plurality of substrate pads 22. A protection layer 24 may cover the substrate 20 except for the substrate pad 22. The chip pad 12 may correspond to and superpose over the substrate pad 22.

A solder bump 70 may be formed between the chip pad 12 and the corresponding substrate pad 22. A metal stud 60 may be formed within the solder bump 70. The solder bump 70 may have a concave shape in the middle thereof. In this embodiment, the concave shape may be symmetrical, provided on all sides of the solder bump 70, and extend the entire length of the solder bump 70 existing between the semiconductor chip 10 and the substrate 20. It will be appreciated, however, that the invention is not limited to the specific concave shape illustrated in FIG. 4. For example, only a portion of the length of the solder bump 70 may have a concave shape and/or the concave shape may be asymmetrical.

As used in this specification, the term “concave shape” refers to a shape in which the solder bump 70 has a profile that is widest at a solder bump surface in contact with at least one of the semiconductor chip 10 and the substrate 20. It will be appreciated that the term “concave shape” is not limited to a surface having a curved profile. For example, the solder bump 70 could have a simple tapered shape (in which all side surfaces have profiles that extend along a straight line) that tapers toward the substrate pad 22, and such a solder bump may be considered as having a concave shape. The term “concave shape” precludes a solder bump having a portion, which exists between the semiconductor chip and the substrate, of a width that is greater than both a width of the chip pad and a width of the substrate pad.

Referring again to FIG. 4, the metal stud 60 may have a cylindrical shape. Those skilled in the art will appreciate, however, that metal studs having varied and alternative shapes may be suitably implemented. For example, the metal stud 60 may taper toward one end or both ends or have a geometrical shape with flat side faces and/or curved side faces. Further, in the exemplary embodiment depicted in FIG. 4, only a single metal stud 60 is provided for each solder bump structure. However, the invention is not limited to a one-to-one correspondence between the metal studs 60 and the solder bumps 70 since more than one metal stud 60 may be provided for each solder bump structure.

The solder bump 70 may electrically and mechanically connect the semiconductor chip 10 with the substrate 20. The solder bump 70 may serve as a channel of electrical signals and a mechanical joint between the semiconductor chip 10 and the substrate 20. Although not shown, a space between the semiconductor chip 10 and the substrate 20 may be filled with an underfill material to improve the bonding strength of the solder bump 70.

The solder bump structure having a concave shape may avoid limitations associated with conventional solder bump structures. For example, the width of the UBM 16 may be larger than the width of the concave portion of the solder bump 70. The width of the UBM 16 may be reduced to provide a flip chip package with solder bump structures located at a finer pitch than may be achieved using conventional solder bump structures.

The metal stud 60 may uniformly maintain the distance between the semiconductor chip 10 and the substrate 20, thereby facilitating an underfill process. Further, the metal stud 60 may improve the bonding strength of the solder bump 70 and may reduce bump crack propagation due to thermal stresses.

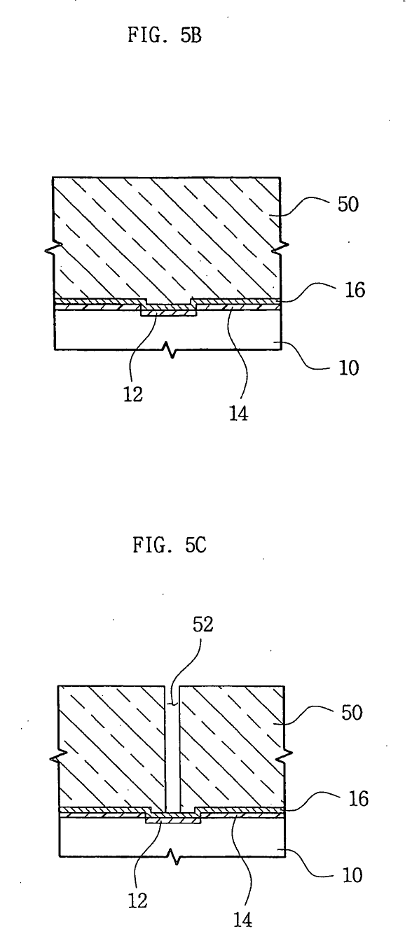

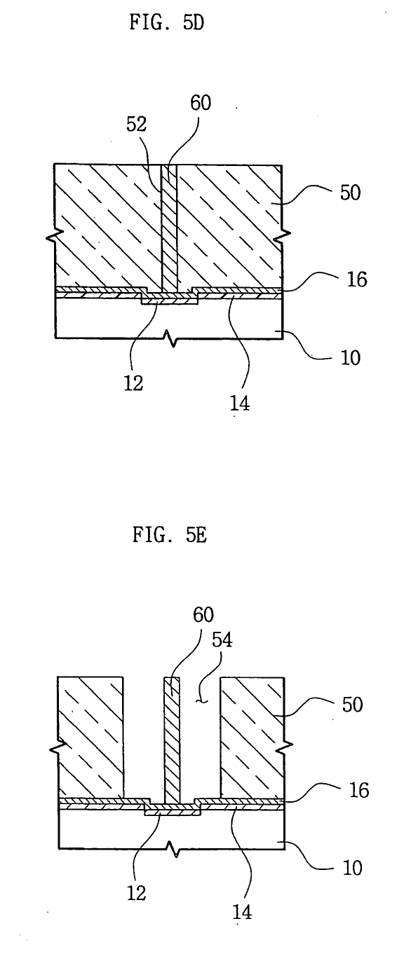

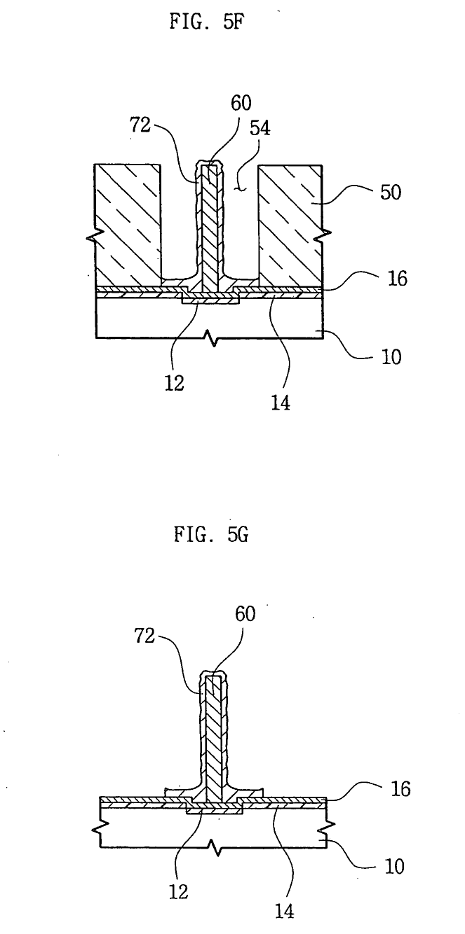

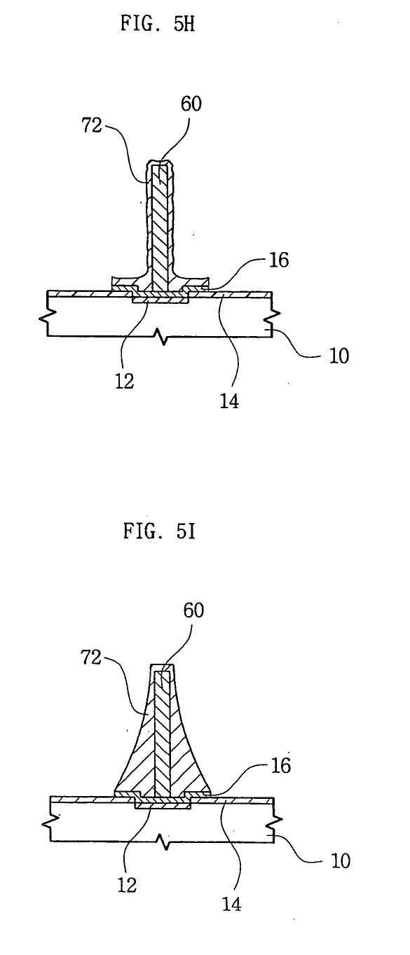

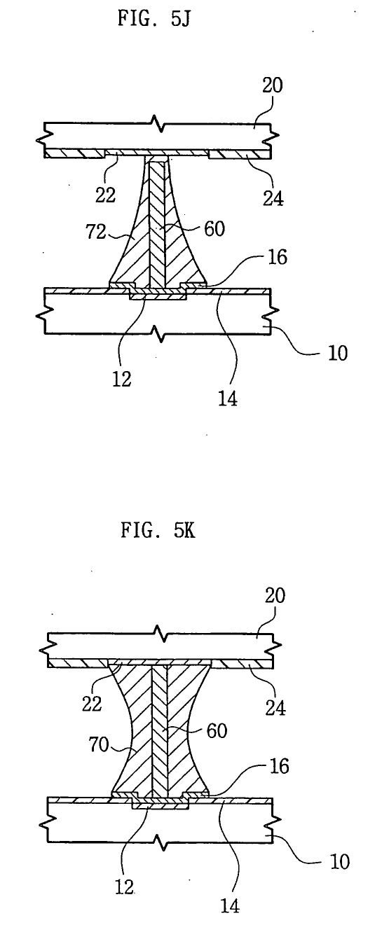

FIGS. 5A through 5K are cross-sectional views of a method that may be implemented for manufacturing the solder bump structure depicted in FIG. 4, and in accordance with an exemplary embodiment of the present invention. Referring to FIG. 5A, a UBM 16 may be formed on a chip pad 12 and a passivation layer 14 of a semiconductor chip 10. The chip pad 12 and passivation layer 14 may be formed on the active surface of the semiconductor chip 10 by a conventional wafer fabrication process. The semiconductor chip 10 may be a single chip separated from a wafer or a chip on the wafer. The chip pad 12 may be made of aluminum (Al) and the passivation layer 14 may be made from one or more of silicon nitride, silicon oxide and polyimide. The UBM 16 may be formed from one or more of Cr, Cu, Ni, TiW and NiV by a sputtering method. The chip pad 12, the passivation layer 14 and the UBM 16 may be fabricated from other suitable materials, as is well known in this art. Further, the UBM 16 may be fabricated using techniques other than the sputtering method, as is well known in this art. The UBM 16 may serve as an adhesive layer, a diffusion preventive layer and/or a solder wetting layer.

Referring to FIG. 5B, a photoresist 50 may be applied on the UBM 16. The thickness of the photoresist 50 may determine the height of a metal stud and a solder bump to be subsequently formed. Ultimately, the thickness of the photoresist 50 may determine a distance between the semiconductor chip 10 and a substrate 20. In an exemplary embodiment, the photoresist 50 may be a positive photoresist. However, in an alternative embodiment, the photoresist 50 may be a negative photoresist.

Referring to FIG. 5C, the photoresist 50 may be exposed and developed to form a first opening 52. The first opening 52 may expose a portion of the UBM 16 on the chip pad 12.

Referring to FIG. 5D, the metal stud 60 may be formed by filling the first opening 52 with a metal material. The metal stud 60 may be made of Ni, Cu, Pd or Pt. Those skilled in the art will appreciate that the metal stud 60 may be fabricated from other suitable materials. The metal stud 60 may be formed by an electroplating method, or some other suitable method that is well known in this art.

Referring to FIG. 5E, a second exposure and development process of the photoresist 50 may form a second opening 54 to expose the metal stud 60. The second opening 54 may determine the size of the UBM 16. If a negative photoresist is used, the photoresist used in forming the first opening may be removed and a new photoresist may be applied for forming the second opening.

Referring to FIG. 5F, solder 72 may be plated on the surfaces of the metal stud 60 and the UBM 16 in the second opening 54. The quantity of the solder 72 used in the plating may be smaller than that taught by conventional teachings. Conventionally, the distance between the semiconductor chip and the substrate may be determined by the size of the solder bump, or the quantity of the solder. In example embodiments of the present invention, the distance between the semiconductor chip and the substrate may be determined by the metal stud 60. The solder 72 may be formed from one or more of Sn, Pb, Ni, Au, Ag, Cu and Bi. The solder 72 may be some other suitable material, as is well known in this art. Further, it will be appreciated that the metal stud 60 and the solder 72 may be fabricated from the same material or different materials.

Referring to FIG. 5G, the remaining photoresist 50 may be removed. Referring to FIG. 5H, an exposed portion of the UBM 16 may be removed using the solder 72 as a mask. Referring to FIG. 5I, a solder reflow process may form the solder 72 into a cone shape. The invention is not, however, limited to the cone shape as other shapes may result from the reflow process depending on the shape of the metal stud 60, the solder selected materials, reflow temperatures, reflow processing times, etc.

Referring to FIG. 5J, the substrate 20 may be connected to the semiconductor chip 10 by the solder 72. A pre-solder may be applied to the substrate pad 22 of the substrate 20 before the interconnection. Referring to FIG. 5K, a second solder reflow process may form a solder bump 70 having a concave shape. The concave shape may result due to the surface tension and wetting property of the melted solder 72.

In accordance with exemplary embodiments of the present invention, the solder bump structure having a concave shape may avoid limitations of the solder bump size and the distance between the solder bumps associated with conventional structures. Thus, the size of the UBM may be reduced so that the solder bump structure may allow a flip chip package having a finer pitch.

The metal stud 60 within the solder bump 70 may more uniformly maintain the distance between the semiconductor chip 10 and the substrate 20 and allow an underfill process regardless of the solder bump size. Further, the metal stud 60 may improve the bonding strength of the solder bump 70 and reduce bump crack propagation which may occur due to thermal stresses.

Although exemplary, non-limiting embodiments of the present invention have been described in detail, it will be understood that many variations and/or modifications of the basic inventive concepts, which may become apparent to those skilled in the art, will fall within the spirit and scope of the present invention as defined in the appended claims. For example, in the disclosed exemplary embodiments, the metal stud 60 and solder 72 are formed on the chip pad 12 of the semiconductor chip 10. However, the invention is not so limited since the metal stud 60 and the solder 72 may be formed on the substrate pad 22 of the substrate 20. In this alternative embodiment, the photoresist 50 depicted in FIGS. 5B-F may be formed on the substrate 20.

Further, the solder bumps may be of varied and alternative concave shapes. For example, the concave shaped solder bump 70 may have an enlarged intermediate section, with the enlarged intermediate section 100 having a width that is less than the widths of both the upper surface of the solder bump 70 (which is in contact with the UBM 16) and the lower surface of the solder bump 70 (which is in contact with the substrate pad 22).

The concave shaped solder bump 70 may have an “I” shape, with the widest portion of solder bump 70 being the respective surfaces in contact with the UBM 16 and the substrate pad 22. The upper and the lower leg portions of the “I” shape may have widths that are equal to or less than the respective surfaces of the solder bump 70 contacting the UBM 16 and the substrate pad 22.

The concave solder bump 70 may have an asymmetrical shape. For example, one side of the solder bump 70 may curve gradually inward, while the other side of the solder bump 70 may taper along a straight line toward the substrate pad 22. In this case, the widest portion of the solder bump 70 may be the surface of the solder bump 70 in contact with the UBM 16. All other portions of the solder bump 70 may have widths that are equal to or less than the surface of the solder bump 70 contacting the UBM 16.

1.-13. (canceled)

14. A method for manufacturing a solder bump, the method comprising:
forming a metal stud on a chip pad of a semiconductor chip;
forming a solder on a surface of the metal stud;
locating the metal stud on a substrate pad of a substrate; and
reflowing the solder to form a solder bump.

15. The method of claim 14, wherein forming the metal stud comprises:
applying a photoresist on the semiconductor chip;
forming an opening in the photoresist; and
filling the opening with a metal material.

16. The method of claim 15, wherein the photoresist is a positive photoresist.

17. The method of claim 15, wherein forming the solder comprises:
forming a second opening in the photoresist to expose the metal stud; and
plating an exposed surface of the metal stud with the solder.

18. The method of claim 14, further comprising applying a pre-solder on the substrate pad of the substrate before the metal stud is located on the substrate pad of the substrate.

19. The method of claim 14, further comprising forming an under barrier metallurgy (UBM) on the chip pad of the semiconductor chip before the metal stud is formed on the chip pad of the semiconductor chip.

20. A method for manufacturing a solder bump, the method comprising:
forming at least one UBM on an active surface of a semiconductor chip having a chip pad;
applying a photoresist on the UBM;
forming a first opening in the photoresist to expose a portion of the UBM;
filling the first opening with a first solder to form a metal stud;
forming a second opening in the photoresist to expose the metal stud;
plating surfaces of the metal stud and the UBM with a second solder;
removing the photoresist;
removing the UBM using the second solder as a mask;
reflowing the second solder;
locating the metal stud on a substrate pad of a substrate; and
reflowing the second solder to form a solder bump having a concave shape in the middle thereof.

21. The method of claim 20, wherein the first and the second solders are the same material.

22. The method of claim 20, wherein the first and the second solders are different materials.

23. (canceled)

24. A solder bump structure fabricated in accordance with the method of claim 14.

25. A solder bump structure fabricated in accordance with the method of claim 20.
